(19) United States
(12) Patent Application Publication
(10) Pub. No.: US 2023/0057946 A1
(43) Pub. Date: Feb. 23, 2023

(54) ENHANCED COLOUR CONVERSION

(71) Applicant: PLESSEY SEMICONDUCTORS LTD, Plymouth (GB)

(72) Inventors: Andrea Pinos, Plymouth (GB); Samir Mezouari, Plymouth (GB)

(21) Appl. No.: 17/798,648

(22) PCT Filed: Feb. 9, 2021
(86) PCT No.: PCT/GB2021/050295

§ 371 Date: Aug. 10, 2022

(30) Foreign Application Priority Data
Feb. 14, 2020 (GB) 2002087.1

(51) Int. Cl. H01L 33/50; H01L 33/10; H01L 33/00; H01L 33/06; H01L 33/32

(52) U.S. Cl. CPC H01L 33/50; H01L 33/10; H01L 33/0075; H01L 33/06; H01L 33/32

(57) ABSTRACT

A method of forming a light emitting structure, the light emitting structure comprising: a light emitting region configured to emit light having a primary peak wavelength; a partially reflective region; a reflective region; and colour conversion region, wherein the light emitting region is positioned at least partially between the partially reflective layer and the reflective layer and the partially reflective region is positioned at least partially between the colour conversion region and the light emitting region, wherein the partially reflective region is configured to reflect light of a predetermined range of wavelengths and allow light outside the predetermined range of wavelengths to pass through the partially reflective region, wherein the primary peak wavelength is outside the predetermined range of wavelengths.

### FIELD OF THE INVENTION

The invention relates to light emitting structures and methods of forming light emitting structures. In particular, but not exclusively, the invention relates to improved colour conversion in light emitting diode structures.

### BACKGROUND OF THE INVENTION

It is known that light emitting diode (LED) devices provide efficient sources of light for a wide range of applications. LED light sources are used to provide conventional white light, and/or multi-colour light emission. For example, multi-colour light emission includes red, green and/or blue emission suitable for display applications. The desired wavelengths of light provided for by LEDs are typically achieved using a combination of a pump source LED with colour conversion material, such as a phosphor or quantum dots (QDs), for example. Such pump source LEDs generate light with a primary peak wavelength output and stimulate emission of light of a different wavelength in a colour conversion material. For example, blue light Nitride material LEDs (emitting light with a primary peak wavelength of approximately 450 nm) are used to provide white colour converted light LED emission. Blue Nitride material LEDs are also used to provide red colour converted light LED emission and green colour converted light LED emission.

However, whilst pump source LEDs, such as blue Nitride-based material LEDs, are available with high quality, efficient light emission, the application of colour conversion material to achieve light of a desired colour typically results in colour converted LEDs with reduced efficiency in light emission compared with the source LEDs that are used to pump the colour conversion material. Such reduced efficiency is due to, for example, absorption in the colour conversion material of light generated by the source LEDs. Accordingly, a variety of optical coating methods have been used to reduce the losses due to the absorption of light in the colour conversion material. However, such conventional optical coatings are expensive and difficult to implement in mass production.

Accordingly, it would be beneficial to enable more efficient light extraction in colour converted LEDs that use colour conversion techniques to provide light of desired wavelengths.

### SUMMARY OF THE INVENTION

In order to mitigate for at least some of the above-described problems, there is provided:

A method of forming a light emitting structure, the light emitting structure comprising: a light emitting region configured to emit light having a primary peak wavelength; a partially reflective region; a reflective region; and a colour conversion region, wherein the light emitting region is positioned at least partially between the partially reflective region and the reflective region and the partially reflective region is positioned at least partially between the colour conversion region and the light emitting region, wherein the partially reflective region is configured to reflect light of a predetermined range of wavelengths and allow light outside the predetermined range of wavelengths to pass through the partially reflective region, wherein the primary peak wavelength is outside the predetermined range of wavelengths.

Further, there is provided a light emitting structure comprising: a light emitting region configured to emit light having a primary peak wavelength; a partially reflective region; a reflective region; and a colour conversion region, wherein the light emitting region is positioned at least partially between the partially reflective region and the reflective region and the partially reflective region is positioned at least partially between the colour conversion region and the light emitting region, wherein the partially reflective region is configured to reflect light of a predetermined range of wavelengths and allow light outside the predetermined range of wavelengths to pass through the partially reflective region, wherein the primary peak wavelength is outside the predetermined range of wavelengths.

Advantageously, a light emitting structure formed in this way provides improved colour conversion efficiency, minimizes the amount of colour conversion material required and is suitable for mass manufacturing. Beneficially, the method is applicable to LEDs of different sizes, including micro-LEDs, capable of realising white LED, or multi-colour LED displays and is suitable for the mass transfer of individual LEDs, micro-LEDs, and/or monolithic LED arrays.

Preferably, the partially reflective region comprises a Distributed Bragg Reflector (DBR). Advantageously, a DBR is incorporated into the growth process, thereby enabling the formation of crystalline semiconductor layers that provide the required partial reflective functionality without compromising the crystalline quality required to form high quality, efficient light emitting diode devices.

Preferably, the reflective region comprises a Silver (Ag) based mirror. Advantageously, a highly reflective layer is incorporated into the structure, thereby increasing the re-use of backscattered light and light that is not emitted by the colour conversion region, but that propagates back through the structure, falling incident on the Ag-based mirror. Beneficially, Ag is used simultaneously to form the mirror layer and provide eutectic bonding to a handling device, thereby serving a dual purpose.

Preferably, the method comprises depositing the reflective region on a light emitting device comprising the light emitting region. Advantageously, light emitting devices, such as light emitting diode devices may be provided and known deposition techniques used to provide the reflective region without compromising the quality of the light emitting device and whilst enabling at least visible and/or ultraviolet light to be reflected for colour conversion and/or emission.

Preferably, the method comprises growing a light emitting device comprising the light emitting region on a substrate. Advantageously, the structure is formed on a substrate using known techniques, thereby providing high quality material for light generation and extraction.

Preferably, the method comprises growing the partially reflective region prior to the light emitting region. Advantageously, growing the structure in such a manner means that a continuous process can be used to provide high quality material that provides the crystalline quality required to form LED structures, whilst providing the functionality of a partially reflective region.

Preferably, the method comprises removing the substrate, preferably by wet etching. Advantageously, when provided in this manner, a high quality structure is formed on a substrate which is subsequently removed in order to provide the structure that has improved light colour conversion efficiency, thereby reducing the processing burden required to provide the resultant structure.

Preferably, the method comprises depositing the colour conversion region following removal of the substrate. Advantageously, the same region of the structure used for initiating high quality material growth is reused for colour conversion, enabling the formation of a structure without prohibiting colour conversion at a relatively similar position of the structure.

Preferably, the method comprises roughening of the light emitting device following removal of the substrate and prior to forming the colour conversion region. Advantageously, roughening the substrates aids adhesion of the colour conversion region and light extraction without compromising the effect of light emission from the structure.

Preferably, the method comprises bonding a handling device to the reflective region. Advantageously, the structure is handled from the opposite side to the original growth substrate.

Preferably, the light emitting structure comprises a GaN based structure. Advantageously, GaN based structures provide high efficiency emission suitable for colour conversion.

Preferably, the light emitting region comprises one or more epitaxial quantum wells. Advantageously, high quality epitaxial quantum well structures enable efficient light emission in epixtaxial layered devices.

Preferably, the light emitting region is configured to emit light with a primary peak wavelength that corresponds to blue light. Advantageously, blue light has a shorter wavelength than red and green light and can be used to excite emission at a variety of wavelengths, including multicolour and white light emission.

Preferably, the predetermined range of wavelengths comprises wavelengths of light longer than 500 nm such that wavelengths shorter than 500 nm are outside the predetermined range. Advantageously, light with a wavelength less than or equal to 500 nm passes through the partially reflective layer and light with a wavelength more than 500 nm is reflected by the partially reflective layer. Therefore, for example, when blue light is pumping red and green emission from colour conversion material, the red and green emission is reflected away from the structure and the light with a wavelength less than 500 nm passes through the structure in order to be recycled. Therefore, increased output and efficiency from the colour conversion material is enabled.

Further aspects of the invention will be apparent from the description and the appended claims.

### DETAILED DESCRIPTION OF AN EMBODIMENT OF THE INVENTION

A detailed description of embodiments of the invention is described, by way of example only, with reference to the figures, in which:

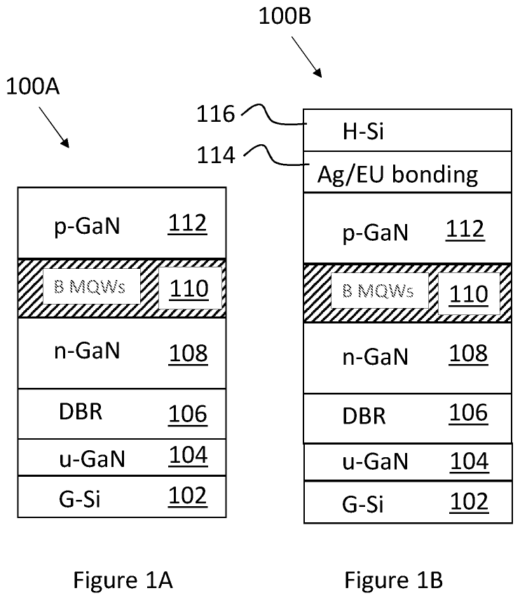

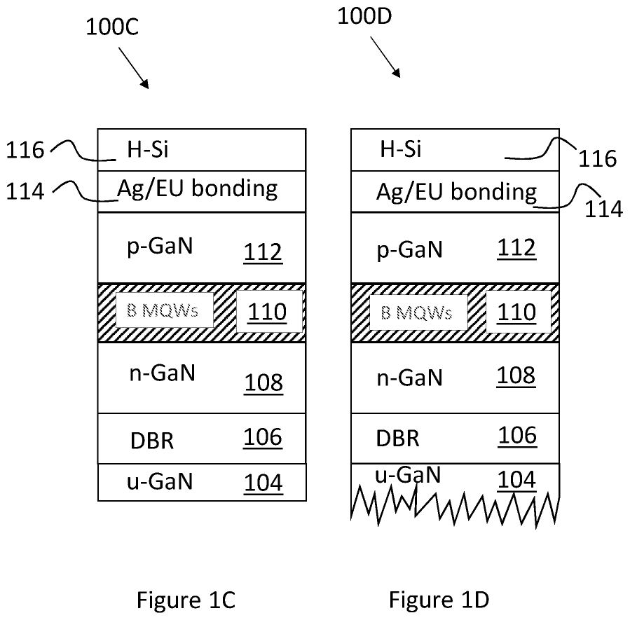

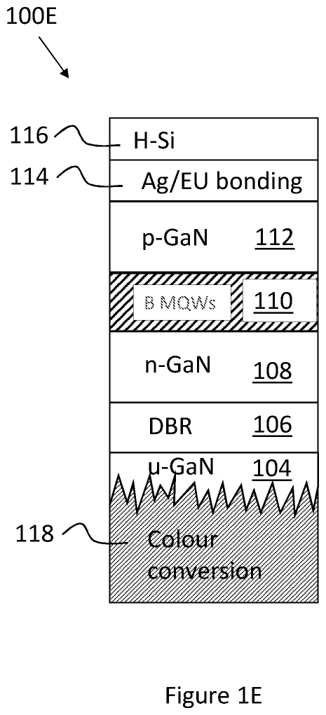

FIG. 1A shows a cross sectional view of a light emitting structure;

FIG. 1B shows a processed version of the cross sectional view of the light emitting structure of FIG. 1A;

FIG. 1C shows a further processed version of the cross sectional view of the light emitting structure of FIG. 1B;

FIG. 1D shows a further processed version of the cross sectional view of the light emitting structure of FIG. 1C;

FIG. 1E shows a further processed version of the cross sectional view of the light emitting structure of FIG. 1D;

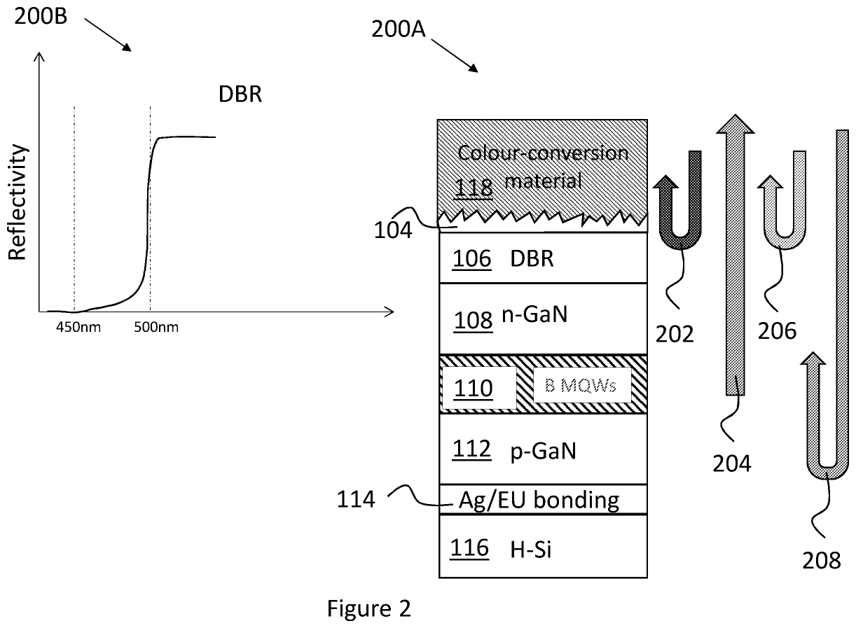

FIG. 2 shows light emission and reflectivity profile of a DBR in a cross sectional view of a light emitting structure produced with reference to FIGS. 1A to 1E;

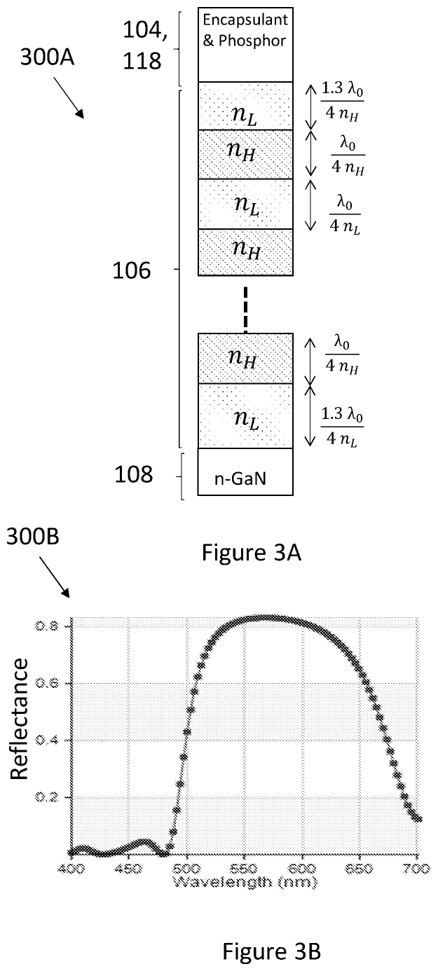

FIG. 3A shows an exemplary DBR structure; and

FIG. 3B shows an exemplary reflectance profile at normal incidence for the DBR of FIG. 3A.

The elegant and advantageous implementation of reflecting and partially reflecting layers in light emitting structures with colour conversion regions provides LED devices, such as micro-LED devices capable of realising white LED or multi-colour LED displays suitable for both mass transfer processes of individual micro-LEDs and for monolithic LED arrays. The synergistic combination of different regions or layers in light emitting structures results in a solution for improved light conversion and extraction compared with known structures. Beneficially, implementations enable the improved functionality whilst maintaining the structural crystalline integrity of epitaxial compound semiconductor light emitting structures and also whilst reducing processing requirements.

A method of forming a light emitting structure 100 is described with reference to FIGS. 1A to 1E. The light emitting structure 100 is an LED structure that uses colour conversion material to provide light with desired wavelengths. The resultant light emitting structure is an LED structure that has a pump source LED and colour conversion region. The method is described by virtue of cross sectional views through the layers of the light emitting structure 100 at different stages in the process of providing a light emitting structure with improved colour conversion. The layers shown in FIGS. 1A to 1E provide regions of light emitting structures with different functional properties. The regions of the light emitting structures with different functional properties are formed from one or more layers of different materials that work together to provide the functional properties (for example, light emitting regions may comprise multiple quantum well structures and partially reflective regions may comprise multiple layers of different refractive indices). In further examples, additional or alternative layers are used to facilitate the concepts described herein.

FIG. 1A shows a light emitting structure 100A that is a blue light emitting LED structure. There is shown a stack of epitaxial compound semiconductor crystalline layers. The epitaxial compound semiconductor crystalline layers are provided by sequential growth of the layers on a growth substrate 102. Beneficially, such epitaxial compound semiconductor crystalline layers formed in this manner can be controlled with high precision to provide high quality material and efficient light emission upon the injection of carriers, from n-type and p-type regions, into a light emitting region.

In FIG. 1A there is shown a growth substrate 102 upon which there is grown a layer of undoped material 104 that is a buffer layer, or buffer region. The undoped material 104 is a layer of undoped Gallium Nitride (u-GaN). Advantageously, the use of such an undoped GaN facilitates the growth of III-V nitride based LED devices with high light generation efficiency, and thus is used to provide an efficient source of light emission for colour conversion using colour conversion material. Further, the undoped material provides a region that is transparent to at least visible and ultraviolet light and is further processed in order to enable integration of colour conversion material into the eventual light emitting structure.

On top of the undoped material 104 there is shown a layer that is a partially reflective region 106. The growth substrate 102 is a growth silicon substrate. The partially reflective region 106 is a distributed Bragg reflector (DBR). In an example the DBR is formed on an n-type semiconductor layer using the method described in Zhang et al., ACS Photonics, 2, 980 (2015). The partially reflective region 106 is formed in a way that it reflects all wavelengths above 500 nm. Light of longer wavelengths, e.g., green light with a wavelength of 520 nm, is reflected by the partially reflective region 106 and red light with a wavelength of 620 nm, is reflected by the partially reflective region 106.

The partially reflective region 106 is formed from alternating epitaxial crystalline layers of different refractive indices. The refractive indices of the layers, and the thicknesses of the layers, are selected in order to provide a reflectivity response as a function of the wavelength of light incident at the partially reflective region 106. Further, the porosity of the epitaxial crystalline layers forming the partially reflective region 106 is controlled in order to provide the desired reflectivity response as a function of wavelength, since the porosity of the epitaxial crystalline layers is linked to their refractive index.

In an example, alternating high and low refractive index layers form the partially reflective region 106, whereby the thickness of each of the high (n_{H}) and low (n_{L}) refractive index layers is chosen so that the product of the thickness and the reciprocal index of refraction of the layer is λ 0/4, whereby λ0 is the central wavelength of a high reflectivity response between +/−λe around λ0 in accordance with the following equation:

$$λ e = λ 0 / [ 1 - ( \frac{2}{π} ) {sin}^{- 1} ( \frac{{n}_{H} - {n}_{L}}{{n}_{H} + {n}_{L}} ) ]$$

FIG. 3A illustrates a cross sectional view of an example of such alternating high and low refractive index layers 300A forming a partially reflective region 106, as well as an associated reflectivity response 300B, as a function of wavelength. Alternating high and low refractive index layers 300A start and terminate at the bottom and top of the structure with low refractive index layers that are 1.3 times the thickness of the other low refractive index layers (1.3λ0/4 instead of λ0/4) in the other alternating layers in the structure 300A, providing the reflectivity response at normal incidence seen at FIG. 3B.

Whilst the specific structure arranged to provide the desired effect can be implemented in different ways, in an example, the partially reflective region 106 has a structure 300A as described with respect to FIG. 3A. The partially reflective region 106 comprises alternating high and low refractive index layers. Where the structure is formed for a wavelength of light of λ0=570 nm, a first layer has a thickness of 121.8 nm (1.32λ0/4 instead of λ/4) and is formed from Gallium Nitride with a porosity of 70%. The next layer is formed from a Gallium Nitride layer that is not porous and is 61.7 nm thick. The next layer is another Gallium Nitride layer with a porosity of 70% and thickness of 93.7 nm. The next layer is another Gallium Nitride Layer that is not porous and is 61.7 nm thick. Four more pairs of alternating Gallium Nitride 93.7 nm thick with a porosity of 70% and non-porous 61.7 nm thick Gallium Nitride are formed. A final layer of 70% porous Gallium Nitride of 121.8 nm terminates the structure (1.3λ0/4 instead of λ0/4). The structure described with respect to FIG. 3A provides a reflectance at normal incidence as a function of wavelength as shown at the reflectivity response 300B of FIG. 3B.

Whilst the partially reflective region 106 is formed in the above manner, alternatively, or additionally the structure and/or layers of the partially reflective region 106 are formed from different layers and materials, with different porosities and thicknesses that provide the required reflectivity response. For example, it is known that the porosity of a material can be changed in order to change its refractive index (e.g., see M. M. Braun, L. Pilon, “Effective optical properties of non-absorbing nanoporous thin films”, This Solid Films 496 (2006) 505-514). For example, the refractive index for porous Gallium Nitride may vary as a function of the percentage porosity in accordance with the following equation: nₚ=\sqrt{(1−p)·n_{GaN}²+p}, where p is the percentage porosity and n is the refractive index. In an example, for a wavelength of 450 nm, the refractive index of porous Gallium Nitride is 2.44 at 0% porosity, 2.34 at 10% porosity, 2.23 at 20% porosity, 2.12 at 30% porosity, 2.00 at 40% porosity, 1.87 at 50% porosity, 1.73 at 60% porosity, 1.58 at 70% porosity, 1.41 at 80% porosity and 1.22 at 90% porosity. Therefore, advantageously, DBRs with the properties required to provide the reflectivity profiles herein are formable using alternating layer of GaN with different porosities, whilst maintaining the crystalline structure to form light emitting structures of high quality material. Alternatively, or additionally, the concept is applicable to different materials.

Advantageously, the partially reflective region 106 is formed as part of a continuous process that forms the light emitting structure 100A, thereby to provide higher quality material and reduce the processing burden. Beneficially, the partially reflective region 106 is grown prior to the light emitting region 110. This provides a structure that can be grown in a continuous process, with high quality, whilst enabling the structure to be used in the manner described below.

Whilst the partially reflective region 106 is a distributed Bragg reflector (DBR), in further examples the partially reflective region 106 is additionally, or alternatively, formed using different methods whilst maintaining the functionality of enabling reflection of some wavelengths of light and transmission of different wavelengths of light.

On top of the partially reflective region 106 there is an n-type region 108. The n-type region 108 is n-doped Gallium Nitride (n-GaN). On top of the n-type region 108 there is a light emitting region 110. The light emitting region 110 is a blue light emitting region 110. On top of the blue light emitting region 110, there is grown a p-type region 112. The p-type region is p-doped Gallium Nitride (p-GaN). The light emitting structure 100A is based on a typical blue LED structure. In further examples, alternative blue light emitting structures are used, with additional or alternative layers.

Whilst the n-type region 108 is n-doped GaN, in further examples, additionally, or alternatively, the n-type region 108 comprises different materials. Whilst the p-type region 112 is p-doped GaN, in further examples, additionally, or alternatively, the p-type region 112 comprises different materials.

Whilst the growth of epitaxial GaN-based materials on a silicon growth substrate 102 is shown, in further examples, additional or alternative intervening layers are used in order to account for a lattice mismatch between the silicon substrate 102 and the subsequently grown layers, such as the partially reflective region 106, the n-type region 108, the light emitting region 110 and the p-type region 112. In an example, the growth substrate 102 comprises silicon with an Aluminium Nitride (AlN) buffer layer. In further examples, the growth substrate 102 comprises an undoped GaN region.

Once the light emitting structure 100A of FIG. 1A has been provided, the light emitting structure 100A is bonded to a handling device 116. This is shown at FIG. 1B. FIG. 1B shows a cross sectional view of the light emitting structure 100A that has been processed to provide the processed light emitting structure 100B of FIG. 1B. The light emitting structure 100A is bonded to a handling device 116 by a reflective region 114. The reflective region 114 comprises a highly reflective Ag (silver) based mirror that has been deposited on the p-type region 112 and that has been processed in order to enable eutectic bonding of the handling device 116 to the p-type region 112. The handling device 116 is a silicon wafer and in an example is beneficially used for its physical properties, such as thermal and structural properties. In further examples additional and/or alternative materials are used to form the handling device 116. In further examples, additional and/or alternative materials are used to form the reflective region 114, for example, the reflective region 114 may use a different method to enable bonding to the handling device 116, e.g., using a separate bonding layer and reflective layer. In further examples, the reflective region 114 is a mirror formed from other materials. The reflective region 114 is arranged to reflect at least visible and/or ultraviolet wavelengths of light, including the primary peak wavelength of light emitted by the light emitting region 110. Beneficially, light emitted by the light emitting region 110 that is backscattered towards the reflective region 114, and light that is recycled into the light emitting structure through the partially reflective region 106, is reflected in the direction of the partially reflective region 106 and the colour conversion region 118, thereby to enhance colour conversion and light output from the light emitting structure.

Once the light emitting structure 100B of FIG. 1B has been provided, the light emitting structure 100B can be handled using the handling device 116 to enable further processing of the structure. The light emitting structure 100B is processed in order to remove the growth substrate 102. This is shown at FIG. 1C. FIG. 1C shows a cross sectional view of the light emitting structure 100B that has been processed to provide the processed light emitting structure 100C of FIG. 1C. The growth substrate 102, which is a silicon growth wafer, is removed by wet etching with KOH solution, hydrofluoric acid and nitric acid, BOE, or similar wet etching solutions. Where a buffer layer has been formed on the growth substrate 102 prior to growth of the subsequent light emitting structure, the buffer layer is optionally removed by dry etching.

Once the light emitting structure 100C of FIG. 1C has been provided, the light emitting structure 100C is processed in order to roughen the undoped material 104. This is shown at FIG. 1D. FIG. 1D shows a cross sectional view of the light emitting structure 100C that has been processed to provide the processed light emitting structure 100D of FIG. 1D.

Once the light emitting structure 100D of FIG. 1D has been provided, the light emitting structure 100D is processed in order to provide the colour conversion material on the roughened undoped region 104. This is shown at FIG. 1E. FIG. 1E shows a cross sectional view of the light emitting structure 100D that has been processed to provide the processed light emitting structure 100E of FIG. 1E. The colour conversion material 118 is a phosphor. Alternatively, or additionally, the colour conversion material 118 comprises different means to convert wavelengths of light from a pump source LED, for example using quantum dots (QDs) or other quantum confining structures, such as quantum wells.

Advantageously, the removal of the growth substrate 102 in order to deposit a colour conversion material 118, in combination with the use of a partially reflective region 106 and a reflective region 114 enables increased light output and efficiency from the colour-converted light. Beneficially, the elegant arrangement of the structure results in an efficient process flow that is suitable for mass manufacturing, as the growth of high quality light emitting structures is provided and light conversion is improved. Beneficially, the increase in light conversion efficiency means that less colour conversion material is used. This is advantageous in respect of cost and processing and means that thinner, more efficient layer of colour conversion material 118 are used.

The light emitting structure 100A of FIG. 1A is formed using epitaxial compound semiconductor growth techniques such as metalorganic chemical vapour deposition (MOCVD) and molecular beam epitaxy (MBE). Additionally, or alternatively, the light emitting structure 100A is formed using any appropriate technique. Whilst the light emitting structures 100A is an LED structure, in further examples, additionally, or alternatively, the light emitting structure 100A is a different light emitting structure benefitting from the use of a partially reflective layer selectively to control wavelengths of light passing through the whole light emitting structure.

The growth of the epitaxial crystalline compound semiconductor layers described above is performed using growth/deposition on silicon wafers that are used as a growth substrate 102. Alternatively, or additionally, other wafers are used, such as sapphire wafers or freestanding Gallium Nitride (GaN) wafers, for example.

Whilst certain epitaxial crystalline compound semiconductor layers are shown in FIGS. 1A to 1E, the skilled person understands that alternative, or additional, layers are used in further examples. Further, in some examples, some of the epitaxial crystalline compound semiconductor layers are removed whilst maintaining the essence of the concepts described herein.

The light emitting structures described with respect to FIGS. 1A to 1E are formed from Nitride-based materials. In particular, the epitaxial crystalline compound semiconductor layers are Gallium Nitride (GaN) based materials. Whilst the structures described in relation to FIGS. 1A to 1E relate to Nitride-based semiconductor compound materials, the skilled person understands that the concepts described herein are applicable to other materials, in particular to other semiconductor materials, for example other III-V compound semiconductor materials, or II-VI compound semiconductor materials.

The light emitting region 110 is formed to include multiple quantum wells (MQWs). The blue light emitting region 110 includes MQWs that are configured to emit light with a primary peak wavelength that is blue, when carriers radiatively combine in the MQWs. The MQWs are formed from Indium Gallium Nitride (InGaN) that is epitaxially grown between GaN-based layers with the composition of the individual quantum wells being tailored to provide the desired wavelength of light that can be emitted from them. Whilst MQWs are described in the light emitting region 110, alternatively a single quantum well (SQW) layer is used. In further examples the light emitting region 110 comprises quantum dots (QDs) that are configured to emit light when carriers radiatively combine in the QDs. Whilst the primary peak wavelength of light emitted from the light emitting region 110 described with reference to FIGS. 1A to 1E is configured to be blue, in further examples, the light emitting region 108 is additionally, or alternatively, configured to emit light with a different primary peak wavelength, for example ultraviolet light.

Further, the skilled person understands that the provision of the light emitting structure in the manner described results in the efficient and high quality generation of material with reduced processing steps, by incorporating layers in the structure, either in the process of forming the individual light emitting structures, or in the processing steps involved in bringing those individual light emitting structures together and processing the resultant structure. However, the skilled person further understands that in further examples, additional or alternative steps are used to form the structure and the order of the steps is chosen to provide different or additional benefits.

FIG. 2 illustrates the light emission concept from the light emitting structure 100E described at FIG. 1E. The light emitting structure 100E is arranged such that carriers are injected into the light emitting region 110, thereby resulting in radiative recombination and the emission of light with a primary peak wavelength that is blue (approximately 450 nm). Carrier injection occurs as a result of providing electrical contact to the n-type region and to the p-type region. Such electrical contact is provided by the formation of an anode and a cathode (not shown).

Upon excitation of the active, light emitting region 110, light with a primary peak wavelength of 450 nm (blue light) is emitted. The emission of light from the light emitting region 110 is non-uniform, with higher intensity in the directions perpendicular to the lateral planes formed by the quantum well(s) in the light emitting region 110. As demonstrated by the arrows at FIG. 2, some blue light emitted by the light emitting region 110 passes through the n-type region 108 and the partially reflective region 106 in order to excite carriers in the colour conversion material 118. This is shown by an arrow 204. Back-scattered blue light emitted by the light emitting region 110 that passes through the p-type region 112 is reflected by the reflective region 114 and passes through the rest of the light emitting structure 100A in order to excite carriers in the colour conversion material 118.

In contrast, light generated and/or reflected by the colour conversion material 118 and incident on the partially reflective region 106 (for example, when not passing out through other surfaces) is either reflected by the partially reflective region 106, or is transmitted through the partially reflective region 106. Where blue light from the light emitting region 110 generates red light from the colour conversion material 118, the red light that is incident on the partially reflective region 106 is reflected by the partially reflective region 106 and exits the structure, providing light emission from a defined top surface. This is illustrated by an arrow 202. Where blue light from the light emitting region 110 generates green light from the colour conversion material 118, the green light that is incident on the partially reflective region 106 is reflected by the partially reflective region 106 and exits the structure providing light emission from the defined top surface. This is illustrated by an arrow 206. Where blue light from the light emitting region 110 results in blue light from the colour conversion material 118 being emitted (including generated or reflected), the blue light that is incident on the partially reflective region 106 is transmitted by the partially reflective region 106 and passes through the structure, whereby any light incident on the bottom region 114 is reflected and passes through the partially reflective region 106, such that it may be provided with the opportunity to excite emission in the colour conversion material, or exit the structure. This is shown by an arrow 208. Beneficially, light from the colour conversion material 118 is directed away from the light emitting structure 100 through the same defined top surface, whilst light that is directed downwards (away from the top surface and back into the light emitting structure from where light is generated by the pump source LED) is reflected out, or re-used to generate further emission away from the light emitting structure through the defined top surface.

Whilst the colour conversion material is described with reference to the production of red, green and blue light, alternatively or additionally the light generated in the colour conversion material 118 has a broad spectrum, such as white light. In such a case, the partially reflective region 106 provides selective transmission and reflection of light based on the wavelength of light incident at the partially reflective region 106, such that the partially reflective layer is configured to reflect a predetermined range of wavelengths. The predetermined range of wavelengths comprises wavelengths greater than 500 nm.

In further examples, alternatively or additionally, the predetermined range of wavelengths comprises wavelengths of visible light greater than 500 nm, such as wavelengths of light between 500 nm and 740 nm. In further examples, the predetermined range of wavelengths comprises wavelengths greater than 400 nm. Advantageously, shorter wavelength light sources (e.g., UV light sources, for example at approximately 380 nm) are used to pump colour conversion material in a manner that benefits from a partially reflective region 106 and mirror region 114 that increases the efficiency of conversion of light and extraction of light from a light emitting structure, for example where the partially reflective region 106 reflects blue light as well as red and green light. Therefore, in examples, beneficial predetermined ranges of wavelengths of light reflected by the partially reflective region 106 include 400 to 740 nm; 500 to 740 nm; all wavelengths greater than 400 nm; and all wavelengths greater than 500 nm.

Whilst the partially reflective region 106 is configured to reflect light in a predetermined range of wavelengths, in some examples less than 100% of the light incident at the partially reflective region 106 is reflected in the predetermined range of wavelengths (e.g., due to absorption/minor transmission) and the partially reflective region 106 is optimised to reflect light as efficiently as possible in the predetermined range of wavelengths to provide an effect of selective transmission of light from the light emitting region 110 to the colour conversion region 118 such that pump source wavelengths of light from the colour conversion region are recycled in the light emitting structure, hitting the reflective region, before exiting to the colour conversion region once again.

Advantageously, light that does not contribute to the emission from the colour conversion material 118 in the side of the structure opposite to the light emitting region 110 is provided with a further opportunity to be emitted from the structure, either by reflectance at the partially reflective region 106, or by reflectance by the bottom mirror region 114. Beneficially, the amount of light emitted by a colour conversion LED with such a structure is increased and the efficiency of conversion of light is also increased by the use of the partially reflective region 106 in combination with the reflective region mirror region 114.

A reflectivity profile 200B of the partially reflective region 106 described with reference to the LED structure 200A of FIG. 2 is shown. The reflectivity profile is such that light with a wavelength above 500 nm is substantially reflected by the partially reflective region 106, whilst light with a wavelength below 500 nm is substantially transmitted by the partially reflective region 106. A partially reflective region 106 with such properties can be implemented using different methods and structures. An example of such a structure providing functionality that may be used in such a fashion is described above and with reference to FIGS. 3A and 3B.

Whilst the above structures are described with reference to the emission of blue light from the light emitting region and the functionality of the partially reflective region 106 and the reflective region 114 such that blue light excites a colour conversion material 118 in a manner that results in longer wavelengths reflecting at the partially reflective region 106 in order to improve emission of longer wavelengths and shorter wavelengths passing through the partially reflective region 106 in order to be reflected by the reflective region 114 to increase the chances of colour conversion and emission from the colour conversion LED structure 200A, the skilled person understands that these concepts are applicable to light with different primary peak wavelengths emitted by the light emitting region, such that the overall amount of colour-converted light that is emitted from the colour conversion material 118 is improved.

1. A method of forming a light emitting structure, the light emitting structure comprising:
a light emitting region configured to emit light having a primary peak wavelength;
a partially reflective region;
a reflective region; and
a colour conversion region, wherein the light emitting region is positioned at least partially between the partially reflective region and the reflective region and the partially reflective region is positioned at least partially between the colour conversion region and the light emitting region, wherein the partially reflective region is configured to reflect light of a predetermined range of wavelengths and allow light outside the predetermined range of wavelengths to pass through the partially reflective region, wherein the primary peak wavelength is outside the predetermined range of wavelengths, wherein the method comprises:
forming a light emitting device comprising the light emitting region on a substrate;
forming the partially reflective region prior to the light emitting region;
forming undoped material between the substrate and the partially reflective region;
removing the substrate; and
roughening the undoped material following removal of the substrate and prior to forming the colour conversion region on the roughened undoped material.

2. The method according to claim 1, wherein the partially reflective region comprises a Distributed Bragg Reflector.

3. The method according to claim 1, wherein the reflective region comprises a Ag-based mirror.

4. The method according to claim 1, comprising depositing the reflective region on a light emitting device comprising the light emitting region.

5. (canceled)

6. The method according to claim 1, comprising removing the substrate by wet etching.

7. The method according to claim 1, comprising bonding a handling device to the reflective region.

8. The method according to claim 1, wherein the light emitting structure comprises a GaN based structure.

9. The method according to claim 1, wherein the light emitting region comprises one or more epitaxial quantum wells.

10. The method according to claim 1, wherein the light emitting region is configured to emit light with a primary peak wavelength that corresponds to blue light.

11. The method according to claim 1, wherein the predetermined range of wavelengths comprises wavelengths of light longer than 500 nm such that wavelengths shorter than 500 nm are outside the predetermined range of wavelengths.

12. (canceled)

13. (canceled)

14. (canceled)

15. (canceled)

16. A light emitting structure comprising:
a light emitting region configured to emit light having a primary peak wavelength;
a partially reflective region;
a reflective region;
a colour conversion region; and
a roughened region formed from an undoped material between the colour conversion region and the partially reflective region, the roughened region configured to increase light extraction into the colour conversion region, wherein the light emitting region is positioned at least partially between the partially reflective region and the reflective region and the partially reflective region is positioned at least partially between the colour conversion region and the light emitting region, wherein the partially reflective region is configured to reflect light of a predetermined range of wavelengths and allow light outside the predetermined range of wavelengths to pass through the partially reflective region, wherein the primary peak wavelength is outside the predetermined range of wavelengths.

17. The light emitting structure according to claim 16, wherein the partially reflective region comprises a Distributed Bragg Reflector.

18. The light emitting structure according to claim 16, wherein the reflective region comprises a Ag-based mirror.

19. The light emitting structure according to claim 16, comprising a handling device bonded to the reflective region.

20. The light emitting structure according to claim 16, wherein the light emitting structure comprises a GaN based structure.

21. The light emitting structure according to claim 16, wherein the light emitting region comprises one or more epitaxial quantum wells.

22. The light emitting structure according to claim 16, wherein the light emitting region is configured to emit light with a primary peak wavelength that corresponds to blue light.

23. The light emitting structure according to claim 16, wherein the predetermined range of wavelengths comprises wavelengths of light longer than 500 nm such that wavelengths shorter than 500 nm are outside the predetermined range of wavelengths.

24. (canceled)

25. (canceled)

26. (canceled)

27. (canceled)
